(19) United States
(12) Patent Application Publication
(10) Pub. No.: US 2026/0348013 A1
(43) Pub. Date: Nov. 5, 2026

(54) GAS DELIVERY DEVICE, SEMICONDUCTOR PROCESSING DEVICE AND OPERATING METHOD THEREOF

(71) Applicant: ADVANCED MICRO-FABRICATION EQUIPMENT INC. CHINA, Shanghai (CN)

(72) Inventors: Guoyuan WANG, Shanghai (CN); Gancheng HU, Shanghai (CN); Yong JIANG, Shanghai (CN); Shiping GUO, Shanghai (CN); Zhao ZHANG, Shanghai (CN)

(21) Appl. No.: 19/707,109

(22) Filed: Jun. 12, 2026

Related U.S. Application Data
(63) Continuation of application No. PCT/CN2024/130127, filed on Nov. 6, 2024.

(30) Foreign Application Priority Data
Dec. 21, 2023 (CN) 202311776666.1

(51) Int. Cl. C23C 16/455; C23C 16/44; C23C 16/448; C23C 16/52; H10P 72/00

(52) U.S. Cl. CPC C23C 16/45561; C23C 16/4408; C23C 16/4481; C23C 16/45512; C23C 16/45565; C23C 16/52; H10P 72/0402

(57) ABSTRACT

The gas delivery device includes: an evaporation source device, including an inlet and an outlet; a carrier gas supply pipeline, one end in fluid communication with a carrier gas source, the other end in fluid communication with the inlet, and the carrier gas enters the evaporation source device and then carries an evaporation source gas to form a process gas; a process gas supply pipeline, one end in fluid communication with the outlet, and the other end in fluid communication with a process chamber; and a purge gas pipeline, including a purge inlet pipeline in fluid communication with the carrier gas supply pipeline through a first vent line, and a purge outlet pipeline in fluid communication with the process gas supply pipeline through a second vent line, a first control valve disposed on the first vent line, and a second control valve disposed on the second vent line.

### CROSS-REFERENCE TO RELATED APPLICATIONS

This application is a continuation of International Patent Application No. PCT/CN2024/130127, filed on Nov. 6, 2024, which claims the benefit of and priority to Chinese Patent Application No. 202311776666.1, filed on Dec. 21, 2023, the disclosures of both of which are hereby incorporated by reference in their entireties.

### TECHNICAL FIELD

The present disclosure relates to the technical field of semiconductor processing equipment, and in particular to a gas delivery device, semiconductor processing apparatus and an operating method thereof.

### BACKGROUND

As shown in FIG. 1, in a current thin film deposition device 1, one or more substrates 17 are disposed horizontally on a heated substrate holder 16, the substrate holder 16 is formed at the bottom of a process chamber 18, a shower head 15 is disposed at the top of the process chamber 18, and the shower head 15 is configured to deliver a process gas into the process chamber 18. The shower head 15 is connected to a gas delivery device. The gas delivery device includes an evaporation source device 2, the evaporation source device 2 holds a solid or liquid starting material 3, a carrier gas is input into the evaporation source device 2 through a carrier gas line 6, two mass flow controllers 10 and 11 with different flow ranges are disposed on the carrier gas line 6, and the mass flow controller 11, for example, may have a larger flow range than the mass flow controller 10. The mass flow controller 10 or the mass flow controller 11 is selected as required. A heating device is disposed in the evaporation source device 2, so that the solid or liquid starting material 3 is evaporated to form saturated vapor, the carrier gas carries the saturated vapor to enter the shower head 15 for conveying the process gas into the process chamber 18, and the process gas forms a thin film on a surface of the substrate 17.

During the replacement of the evaporation source, the gas delivery device is likely to contaminate the gas pipeline and affect the execution of a subsequent process.

### SUMMARY

### Technical Solution

An objective of the present disclosure is to provide a gas delivery device, semiconductor processing apparatus and an operating method thereof. During the replacement of an evaporation source, the gas delivery device is unlikely to contaminate a gas pipeline and will not affect the execution of a subsequent process.

To solve the above problems, the present disclosure is implemented by the following technical solutions:
a gas delivery device is configured to convey a process gas into a process chamber of semiconductor processing apparatus, and includes: an evaporation source device, including an inlet and an outlet and holding an evaporation source; a carrier gas supply pipeline, where one end of the carrier gas supply pipeline is in fluid communication with a carrier gas source, the other end of the carrier gas supply pipeline is in fluid communication with the inlet, and the carrier gas enters the evaporation source device and then carries a saturated evaporation source gas to form a process gas; a process gas supply pipeline, where one end of the process gas supply pipeline is in fluid communication with the outlet, and the other end of the process gas supply pipeline is in fluid communication with a process chamber; and a purge gas pipeline, including a purge inlet pipeline and a purge outlet pipeline, where the purge inlet pipeline is in fluid communication with the carrier gas supply pipeline through a first vent line, the purge outlet pipeline is in fluid communication with the process gas supply pipeline through a second vent line, a first control valve is disposed on the first vent line, and a second control valve is disposed on the second vent line.

In one embodiment, the first vent line includes a first end and a second end, the first end is in fluid communication with the carrier gas supply pipeline, and the second end is in fluid communication with the purge inlet pipeline; and a mass flow controller and a first pneumatic valve are disposed between the carrier gas source and the first end sequentially along a flow direction of the carrier gas.

In one embodiment, the second vent line includes a third end and a fourth end, the third end is in fluid communication with the process gas supply pipeline, and the fourth end is in fluid communication with the purge outlet pipeline; and a second pneumatic valve and a pressure controller are disposed between the third end and the process chamber along a flow direction of the process gas.

In one embodiment, a gas pipeline is disposed between the upstream of the first pneumatic valve and the downstream of the second pneumatic valve, and a third pneumatic valve is disposed on the gas pipeline.

In one embodiment, a first replacement valve is disposed between the first end and the inlet, and a second replacement valve is disposed between the third end and the outlet.

In one embodiment, the evaporation source device includes a first evaporation source device and a second evaporation source device, the first evaporation source device includes a first inlet and a first outlet, the second evaporation source device includes a second inlet and a second outlet, the carrier gas supply pipeline is in fluid communication with the first inlet, the first outlet is in fluid communication with the second inlet through a series channel, a first replacement valve is disposed between the first end and the first inlet, a second replacement valve and a third replacement valve are disposed on the series channel, a fourth replacement valve is disposed between the third end and the second outlet, the first replacement valve and the second replacement valve are configured to replace the first evaporation source device, and the third replacement valve and the fourth replacement valve are configured to replace the second evaporation source device.

In one embodiment, the gas delivery device further includes a switching channel, where the switching channel includes two opposite ends, one end of the switching channel is in fluid communication with the carrier gas supply pipeline between the first end and a first switching valve, the other end of the switching channel is in fluid communication with the series channel between a second switching valve and a third switching valve, and a switching valve is disposed on the switching channel.

In one embodiment, the gas delivery device further includes a third evaporation source device, where the first evaporation source device is connected to the second evaporation source device in series and then connected to the third evaporation source device in parallel.

In one embodiment, the purge gas pipeline includes a first purge gas pipeline and a second purge gas pipeline, the first purge gas pipeline includes a first purge inlet pipeline and a first purge outlet pipeline, the first purge inlet pipeline is in fluid communication with the first vent line, the first purge outlet pipeline is in fluid communication with the second vent line, the first purge gas pipeline, the first vent line and the second vent line are configured to discharge air in pipelines of the first evaporation source device and the second evaporation source device, the second purge gas pipeline includes a second purge inlet pipeline and a second purge outlet pipeline, the second purge inlet pipeline is in fluid communication with the carrier gas supply pipeline through a third vent line, and the second purge outlet pipeline is in fluid communication with the process gas supply pipeline through a fourth vent line.

In one embodiment, the first purge outlet pipeline is in fluid communication with the second purge inlet pipeline; and the semiconductor processing apparatus further includes a vacuum pump, and the second purge outlet pipeline is in fluid communication with the vacuum pump.

In one embodiment, the carrier gas source of the first evaporation source device and the second evaporation source device is independent of the carrier gas source of the third evaporation source device; and the process gas supply pipeline of the first evaporation source device and the second evaporation source device and the process gas supply pipeline of the third evaporation source device are respectively connected to different inlets of the process chamber.

In one embodiment, the first evaporation source device, the second evaporation source device and the third evaporation source device share the same carrier gas source; and the process gas supply pipeline of the first evaporation source device and the second evaporation source device and the process gas supply pipeline of the third evaporation source device are merged and then connected to the same inlet of the process chamber.

In one embodiment, the gas delivery device further includes: a diluent carrier gas line, where one end of the diluent carrier gas line is in fluid communication with a dilution carrier gas source, and the other end of the diluent carrier gas line is in fluid communication with the process gas supply pipeline and is configured to dilute the process gas output from the evaporation source device to form a diluted process gas; and a dilution process channel, where one end of the dilution process channel is in fluid communication with the process gas supply pipeline, and the other end of the dilution process channel is in fluid communication with the process chamber.

In one embodiment, the process gas supply pipeline of the first evaporation source device and the second evaporation source device is a first process gas supply pipeline, and the process gas supply pipeline of the third evaporation source device is a second process gas supply pipeline. The gas delivery device further includes: a first diluent carrier gas line and a second diluent carrier gas line, where one end of the first diluent carrier gas line is in fluid communication with a first dilution carrier gas source, and the other end of the first diluent carrier gas line is in fluid communication with the first process gas supply pipeline and is configured to dilute the process gas output from the first evaporation source device and the second evaporation source device to form a first diluted process gas; a first dilution process channel, where one end of the first dilution process channel is in fluid communication with the first process gas supply pipeline, the other end of the first dilution process channel is in fluid communication with the process chamber, one end of the second diluent carrier gas line is in fluid communication with a second dilution carrier gas source, and the other end of the second diluent carrier gas line is in fluid communication with the second process gas supply pipeline and is configured to dilute the process gas output from the third evaporation source device to form a second diluted process gas; and a second dilution process channel, where one end of the second dilution process channel is in fluid communication with the second process gas supply pipeline, and the other end of the second dilution process channel is in fluid communication with the process chamber.

In one embodiment, the carrier gas source of the first evaporation source device and the second evaporation source device, the carrier gas source of the third evaporation source device, the first dilution carrier gas source and the second dilution carrier gas source are independent of each other; and a first diluted process gas supply pipeline and a second diluted process gas supply pipeline are respectively connected to different inlets of the process chamber.

In one embodiment, the carrier gas source of the first evaporation source device and the second evaporation source device, the carrier gas source of the third evaporation source device, the first dilution carrier gas source and the second dilution carrier gas source share the same carrier gas source; and a first diluted process gas supply pipeline and a second diluted process gas supply pipeline are merged and then connected to the same inlet of the process chamber.

According to another aspect, the present disclosure further provides semiconductor processing apparatus, including: a process chamber; a base, located at the bottom of the process chamber and configured to carry a wafer; a shower head, disposed opposite to the base; and the gas delivery device, connected to the shower head and configured to convey a process gas into the process chamber.

Correspondingly, the present disclosure further provides an operating method of semiconductor processing apparatus, including: providing the semiconductor processing apparatus; opening the first control valve to evacuate the gas in the carrier gas supply pipeline; and opening the second control valve to evacuate the gas in the process gas supply pipeline.

In one embodiment, the first vent line includes a first end and a second end; the first end is in fluid communication with the carrier gas supply pipeline, and the second end is in fluid communication with the purge inlet pipeline; a first pneumatic valve is disposed between the carrier gas source and the first end sequentially along a flow direction of the carrier gas; the second vent line includes a third end and a fourth end; the third end is in fluid communication with the process gas supply pipeline, and the fourth end is in fluid communication with the purge outlet pipeline; a second pneumatic valve is disposed between the third end and the process chamber along a flow direction of the process gas; and the operating method of the semiconductor processing apparatus further includes: when performing process treatment in the process chamber, closing the first control valve and the second control valve, and opening the first pneumatic valve and the second pneumatic valve.

In one embodiment, a first replacement valve is disposed between the first end and the inlet; a second replacement valve is disposed between the third end and the outlet; and before the step of opening the first control valve and the second control valve, the operating method further includes: closing the first control valve, the second control valve, the first pneumatic valve and the second pneumatic valve, and disassembling the evaporation source device through the first replacement valve and the second replacement valve.

### Beneficial Effects

Compared with the prior art, the technical solution of the present disclosure has the following beneficial effects:
in the gas delivery device provided by the present disclosure, a purge gas pipeline is additionally provided, the purge gas pipeline includes a purge inlet pipeline and a purge outlet pipeline, the purge inlet pipeline is in fluid communication with the carrier gas supply pipeline through a first vent line, the purge outlet pipeline is in fluid communication with the process gas supply pipeline through a second vent line, it is beneficial to discharge the gas in the carrier gas supply pipeline by opening the first control valve on the first vent line, and it is beneficial to discharge the gas in the process gas supply pipeline by opening the second control valve on the second vent line, so that it is beneficial to avoid the adverse influence on the subsequent process caused by undesirable gas remaining in the carrier gas supply pipeline and the process gas supply pipeline.

### BRIEF DESCRIPTION OF THE DRAWINGS

FIG. 1 is a schematic structural view of a thin film deposition device;

FIG. 2 is a schematic structural view of semiconductor processing apparatus according to the present disclosure;

FIG. 3 is a schematic structural view of a gas delivery device in FIG. 2;

FIG. 4 is a schematic structural view of another gas delivery device according to the present disclosure;

FIG. 5 is a schematic structural view of another semiconductor processing apparatus according to the present disclosure;

FIG. 6 is a schematic structural view of yet another semiconductor processing apparatus according to the present disclosure;

FIG. 7 is a schematic structural view of yet another semiconductor processing apparatus according to the present disclosure;

FIG. 8 is a schematic structural view of another gas delivery device according to the present disclosure;

FIG. 9 is a schematic structural view of yet another semiconductor processing apparatus according to the present disclosure;

FIG. 10 is a schematic structural view of yet another semiconductor processing apparatus according to the present disclosure; and

FIG. 11 is a flowchart of an operating method of semiconductor processing apparatus according to the present disclosure.

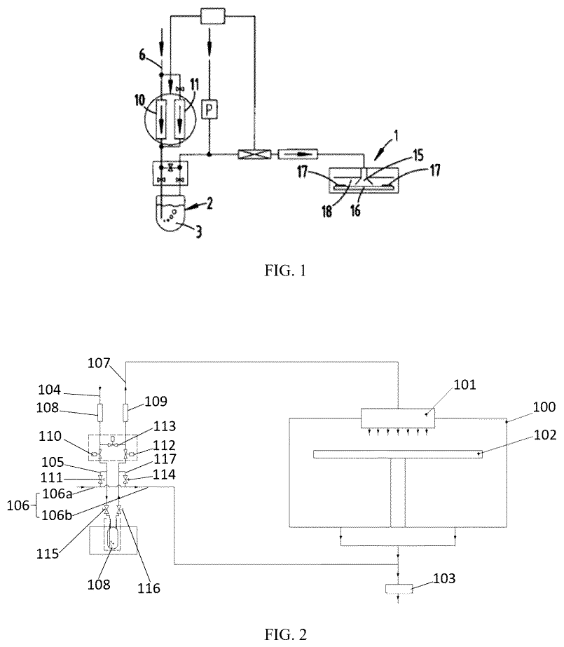

### DETAILED DESCRIPTION OF THE EMBODIMENTS

A gas delivery device and semiconductor processing apparatus proposed by the present disclosure will be further described below in detail with reference to the accompanying drawings and the specific embodiments. The advantages and features of the present disclosure will become clearer from the following description. It should be noted that the drawings are in a very simplified form and all use imprecise scales, which are only used to facilitate and clearly assist the objective of illustrating the embodiments of the present disclosure. In order to make the objectives, features and advantages of the present disclosure more comprehensible, please refer to the accompanying drawings. It should be noted that the structures, proportions, sizes and the like shown in the drawings attached to this specification are only used to match the content disclosed in the specification, for those who are familiar with this technology to understand and read, and are not used to limit the limiting condition of implementation of the present disclosure, so it has no technical substantive meaning, and any modification of structure, change of proportional relationship or adjustment of size shall still fall within the scope covered by the disclosed technical content of the present disclosure without affecting the effect and objective of the present disclosure.

The present disclosure provides a gas delivery device, semiconductor processing apparatus and an operating method thereof. The gas delivery device is additionally provided with a purge gas pipeline, the purge gas pipeline includes a purge inlet pipeline and a purge outlet pipeline, the purge inlet pipeline is in fluid communication with a carrier gas supply pipeline through a first vent line, and the purge outlet pipeline is in fluid communication with a process gas supply pipeline through a second vent line. After an evaporation source device is replaced, the air entering the carrier gas supply pipeline and the process gas supply pipeline is discharged respectively through the first vent line and the second vent line, so that when the gas delivery device is subsequently used, no residual water or oxygen in the air will be in contact with an MO source, thereby avoiding the adverse consequences such as explosion or reaction caused by the contact between the water or oxygen and the MO source.

The detailed description is as follows:
as shown in FIG. 2, semiconductor processing apparatus includes: a process chamber 100; a base 102, located in the process chamber 100 and configured to carry a wafer; and a shower head 101, disposed at the top of the process chamber 100 and disposed opposite to the base 102. The shower head 101 is connected to a gas delivery device and configured to convey a process gas into the process chamber 100.

A thin film deposition process is performed in the process chamber 100. Correspondingly, the semiconductor processing apparatus is a thin film deposition device, for example: a metal-organic chemical vapor deposition device.

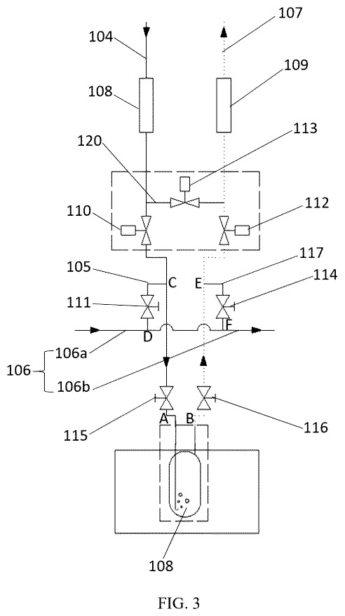

Referring to FIG. 2 and FIG. 3, the gas delivery device includes: an evaporation source device 108, including an inlet A and an outlet B and holding evaporation source liquid; a carrier gas supply pipeline 104, where one end of the carrier gas supply pipeline is in fluid communication with a carrier gas source, the other end of the carrier gas supply pipeline is in fluid communication with the inlet A, and a carrier gas provided by the carrier gas source enters the evaporation source device 108 and then carries an evaporation source gas to form a process gas; a process gas supply pipeline 107, where one end of the process gas supply pipeline is in fluid communication with the outlet B, and the other end of the process gas supply pipeline is in fluid communication with a process chamber 100; and a purge gas pipeline 106, including a purge inlet pipeline 106a and a purge outlet pipeline 106b, where the purge inlet pipeline 106a is in fluid communication with the carrier gas supply pipeline 104 through a first vent line 105, the purge outlet pipeline 106b is in fluid communication with the process gas supply pipeline 107 through a second vent line 117 (as shown in FIG. 3), a first control valve 111 is disposed on the first vent line 105, and a second control valve 114 is disposed on the second vent line 117.

The first vent line 105 includes a first end C and a second end D, the first end C is in fluid communication with the carrier gas supply pipeline 104, and the second end D is in fluid communication with the purge inlet pipeline 106a; and a mass flow controller 108 and a first pneumatic valve 110 are disposed between the carrier gas source and the first end C sequentially along a flow direction of the carrier gas.

The second vent line 117 includes a third end E and a fourth end F, the third end E is in fluid communication with the process gas supply pipeline 107, and the fourth end F is in fluid communication with the purge outlet pipeline 106b; and a second pneumatic valve 112 and a pressure controller 109 are disposed between the third end E and the process chamber 100 along a flow direction of the process gas.

A gas pipeline 120 is disposed between the upstream of the first pneumatic valve 110 and the downstream of the second pneumatic valve 112, and a third pneumatic valve 113 is disposed on the gas pipeline 120. The upstream of the first pneumatic valve 110 is defined according to the flow direction of the carrier gas. Specifically, the upstream of the first pneumatic valve 110 refers to the carrier gas supply pipeline 104 between the mass flow controller 108 and the first pneumatic valve 110. The downstream of the second pneumatic valve 112 is defined according to the flow direction of the process gas. Specifically, the downstream of the second pneumatic valve 112 refers to the process gas supply pipeline 107 between the second pneumatic valve 112 and the pressure controller 109.

When it is necessary to perform process treatment in the process chamber 100, the first pneumatic valve 110 and the second pneumatic valve 112 are opened, and the third pneumatic valve 113, the first control valve 111 and the second control valve 114 are closed, so that the carrier gas enters the evaporation source device 108 from the carrier gas source through the carrier gas supply pipeline 104 and the first pneumatic valve 110. The evaporation source device 108 is provided with a constant-temperature water bath, the constant-temperature water bath maintains a stable temperature, which may be 25 °C, 5 °C and other required water temperatures, and is kept at a constant temperature. The constant-temperature water bath can heat the evaporation source liquid contained in the evaporation source device 108 to form saturated vapor, the carrier gas carries the saturated vapor to form the process gas, and the process gas sequentially passes through the second pneumatic valve 112 and the pressure controller 109 and then enters the process chamber 100 to form a thin film on a surface of the wafer.

Regardless of whether the process treatment is performed in the process chamber 100, the carrier gas source is in a working state. When the process treatment is not performed in the process chamber 100, the first pneumatic valve 110 and the second pneumatic valve 112 are closed, and the third pneumatic valve 113 is opened, so that the carrier gas enters the process chamber 100 through the third pneumatic valve 113. The semiconductor processing apparatus further includes a vacuum pump 103, and the vacuum pump 103 is in fluid communication with the process chamber 100 and is configured to control the pressure in the process chamber 100. When the process treatment is not performed in the process chamber 100, the carrier gas entering the process chamber 100 is pumped away by the vacuum pump 103.

When different processes require different evaporation sources or the evaporation sources do not meet the process requirements, the evaporation source device 108 is required to be replaced. To facilitate the replacement of the evaporation source device 108, a first replacement valve 115 is disposed between the first end C and the inlet A, and a second replacement valve 116 is disposed between the third end E and the outlet B. The evaporation source device 108 can be replaced by disassembling the first replacement valve 115 and the second replacement valve 116.

However, when the first replacement valve 115 and the second replacement valve 116 are disassembled, air can easily enter the carrier gas supply pipeline 104 and the process gas supply pipeline 107. If the air in the carrier gas supply pipeline 104 is not evacuated, the air will enter the evaporation source device 108 along with the carrier gas during the next process. An MO source gas in the evaporation source device 108, for example, is trimethylgallium (TMGa), trimethylaluminum (TMAl), triethylgallium (TEGa), a P-type dopant (Cp2Mg) or trimethylindium (TMIn). The MO source gas is prone to explosion or reaction when exposed to the air. The air entering the process gas supply pipeline 107 will enter the process chamber 100 along with the process gas and be prone to affect the environment in the process chamber 100.

To avoid the above problems, before the next process is performed in the process chamber 100, the air entering the carrier gas supply pipeline 104 and the process gas supply pipeline 107 is respectively discharged through the first vent line 105 and the second vent line 117. Specifically, the first pneumatic valve 110 and the second pneumatic valve 112 are closed, and the third pneumatic valve 113, the first control valve 111 and the second control valve 114 are opened, so that the purge gas in the purge inlet pipeline 106a can purge the air in the carrier gas supply pipeline 104, and the purge gas in the purge outlet pipeline 106b can purge the air in the process gas supply pipeline 107, thereby avoiding the above problems when the process gas is conveyed into the process chamber 100 subsequently.

In this embodiment, one evaporation source device 108 is provided.

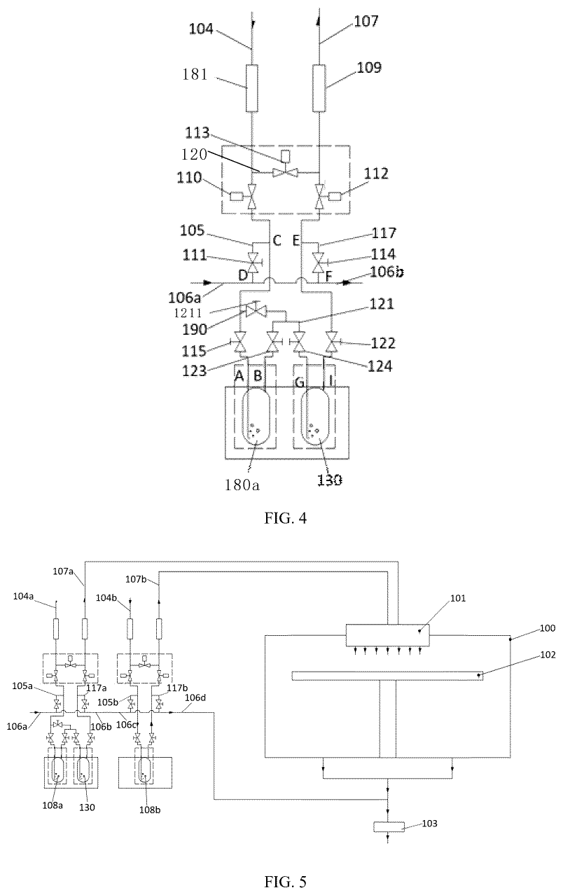

FIG. 4 is a schematic structural view of another gas delivery device according to the present disclosure.

Referring to FIG. 4, the carrier gas supply pipeline 104, the mass flow controller 181, the first pneumatic valve 110, the second pneumatic valve 112, the third pneumatic valve 113, the pressure controller 109 and the process gas supply pipeline 107 are the same as those in the gas delivery device in FIG. 3, and will not be elaborated herein.

In this embodiment, two evaporation source devices are provided, namely, a first evaporation source device 108a and a second evaporation source device 130, the first evaporation source device 108a includes a first inlet A and a first outlet B, the second evaporation source device 130 includes a second inlet G and a second outlet I, the carrier gas supply pipeline 104 is in fluid communication with the first inlet A, the first outlet is in fluid communication with the second inlet G through a series channel 121, a first replacement valve 115 is disposed between the first end C and the first inlet A, a second replacement valve 123 and a third replacement valve 124 are disposed on the series channel 121, a fourth replacement valve 122 is disposed between the third end E and the second outlet I, the first replacement valve 115 and the second replacement valve 123 are configured to replace the first evaporation source device 108a, and the third replacement valve 124 and the fourth replacement valve 122 are configured to replace the second evaporation source device 130.

The gas delivery device further includes a switching channel 190, where one end of the switching channel 190 is in fluid communication with the carrier gas supply pipeline 104 between the first end C and a first replacement valve 115, and the other end of the switching channel 190 is in fluid communication with the series channel between a second replacement valve 123 and a third replacement valve 124, and a switching valve 1211 is disposed on the switching channel 190.

When it is necessary to perform process treatment in the process chamber, the evaporation source liquid in the first evaporation source device 108a and the second evaporation source device 130 is not exhausted, and the first evaporation source device 108a and the second evaporation source device 130 are required for use, the third pneumatic valve 113, the first control valve 111, the second control valve 114 and the switching valve 1211 are closed, the first pneumatic valve 110, the first replacement valve 115, the second replacement valve 123, the third replacement valve 124, the fourth replacement valve 122 and the second pneumatic valve 112 are opened, so that the carrier gas enters the first evaporation source device 108a from the carrier gas supply pipeline 104 and then passes through the second evaporation source device 130 to form a process gas, and the process gas is conveyed into the process chamber 100 through the process gas supply pipeline 107.

When the evaporation source in the first evaporation source device 108a is exhausted and the evaporation source in the second evaporation source device 130 remains, the third pneumatic valve 113, the first control valve 111, the second control valve 114, the first replacement valve 115 and the second replacement valve 123 are closed, and the first pneumatic valve 110, the switching valve 1211, the third replacement valve 124, the fourth replacement valve 122 and the second pneumatic valve 112 are opened, so that the carrier gas enters the second evaporation source device 130 from the carrier gas source through the first pneumatic valve 110, a switching channel 190, a series channel 121 and the third replacement valve 124 sequentially, and the formed process gas is conveyed into the process chamber for process treatment.

It should be noted that when the evaporation source of the first evaporation source device 108a is exhausted and the evaporation source of the second evaporation source device 130 remains, and if the evaporation source of the second evaporation source device 130 can still meet the process requirement, the first evaporation source device 108a may be retained temporarily without replacement.

When all the evaporation source liquid in the first evaporation source device 108a and the second evaporation source device 130 is exhausted, the first evaporation source device 108a and the second evaporation source device 130 are replaced by disassembling the first replacement valve 115, the second replacement valve 123, the third replacement valve 124 and the fourth replacement valve 122.

When the first evaporation source device 108a and the second evaporation source device 130 are disassembled, air tends to enter the carrier gas supply pipeline, the gas pipeline 120 and the process gas supply pipeline 107. To mitigate adverse effects of such air on the subsequent supply, before the next process is performed, the first pneumatic valve 110, the second pneumatic valve 112, the first replacement valve 115, the second replacement valve 123, the third replacement valve 124 and the fourth replacement valve 122 are closed, and the third pneumatic valve 113, the first control valve 111, the second control valve 114 and the switching valve 1211 are opened, so that the air in the carrier gas supply pipeline 104 and the gas pipeline 120 is evacuated by the purge inlet pipeline 106a, and the air in the process gas supply pipeline 107 is evacuated by the purge outlet pipeline 106b. Therefore, the adverse influence of the air introduced during replacement of the first evaporation source device 108a and the second evaporation source device 130 can be avoided.

FIG. 5 is a schematic structural view of another semiconductor processing apparatus according to the present disclosure.

In this embodiment, the evaporation source device includes a first evaporation source device 108a, a second evaporation source device 130 and a third evaporation source device 108b, where the first evaporation source device 108a and the second evaporation source device 130 are connected in series through the series channel, and the first evaporation source device 108a and the second evaporation source device 130 are connected in series and then connected to the third evaporation source device 108b in parallel.

When the first evaporation source device 108a, the second evaporation source device 130 and the third evaporation source device 108b are required to be replaced, air tends to enter the pipelines, and the air entering the pipelines is similar to that in the above embodiment and will not be elaborated herein. To evacuate the air in the pipelines, the first evaporation source device 108a and the second evaporation source device 130 have a first purge gas pipeline, a first purge inlet pipeline 106a of the first purge gas pipeline is in fluid communication with a first vent line 105a, and a first purge outlet pipeline 106b of the first purge gas pipeline is in fluid communication with a second vent line 117a and is configured to discharge the air in the pipelines of the first evaporation source device 108a and the second evaporation source device 130. The third evaporation source device 108b has a second purge gas pipeline, a second purge inlet pipeline 106c of the second purge gas pipeline is in fluid communication with a third vent line 105b, and a second purge outlet pipeline 106d of the second purge gas pipeline is in fluid communication with a fourth vent line 117b and is configured to discharge the air in the pipeline of the third evaporation source device 108b.

The first purge outlet pipeline 106b is in fluid communication with the second purge inlet pipeline 106c, and the second purge outlet pipeline 106d is in fluid communication with a vacuum pump 103 and is configured to discharge the air in the pipeline.

In this embodiment, the carrier gas supply pipeline 104a of the first evaporation source device 108a and the second evaporation source device 130 and the carrier gas supply pipeline 104b of the third evaporation source device 108b are independent of each other; and the process gas supply pipeline 107a of the first evaporation source device 108a and the second evaporation source device 130 and the process gas supply pipeline 107b of the third evaporation source device 108b are independent of each other and respectively connected to different inlets of the shower head 101 to respectively provide the process gas to the process chamber 100 to form a thin film on a surface of the wafer 102.

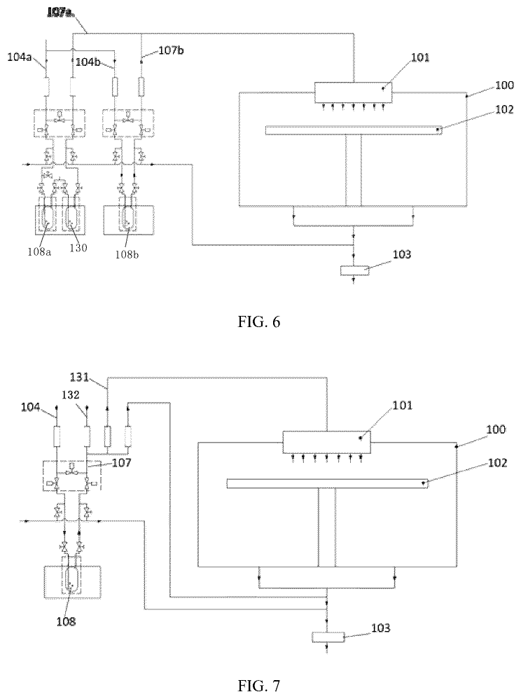

FIG. 6 is a schematic structural view of yet another semiconductor processing apparatus according to the present disclosure.

The embodiment shown in FIG. 6 is the same as the embodiment in FIG. 5 in that: the first evaporation source device 108a and the second evaporation source device 130 are connected in series through the series channel, and the first evaporation source device 108a and the second evaporation source device 130 are connected in series and then connected to the third evaporation source device 108b in parallel.

The embodiment shown in FIG. 6 is different from the embodiment in FIG. 5 in that: in the embodiment in FIG. 5, the carrier gas supply pipeline 104a and the carrier gas supply pipeline 104b are respectively connected to different carrier gas sources, and the process gas supply pipeline 107a and the process gas supply pipeline 107b are respectively connected to different inlets of the shower head 101; and in contrast, in the embodiment in FIG. 6, the carrier gas supply pipeline 104a and the carrier gas supply pipeline 104b are connected to the same carrier gas source, the carrier gas source is divided into two branches to respectively communicate with the carrier gas supply pipeline 104a and the carrier gas supply pipeline 104b, and the process gas supply pipeline 107a and the process gas supply pipeline 107b are merged and then connected to the same inlet of the shower head 101.

In the above embodiment, the process gas from the evaporation source device has a relatively high concentration and is suitable for the situation where the process chamber 100 requires a high-concentration process gas. When the process chamber 100 requires a low-concentration process gas, it can be achieved by the following design:

FIG. 7 is a schematic structural view of yet another semiconductor processing apparatus according to the present disclosure.

The carrier gas supply pipeline 104, the evaporation source device 108 and the process gas supply pipeline 107 in the gas delivery device in FIG. 7 are the same as those in the embodiment shown in FIG. 2, and will not be elaborated herein.

In this embodiment, the carrier gas is conveyed into the evaporation source device 108 from the carrier gas source through the carrier gas supply pipeline 104 to form a mixed gas of saturated evaporation source gas and carrier gas, that is, form a process gas; and the process gas is conveyed to the shower head 101 to form a thin film on a surface of a wafer on a base 102 in the process chamber 100.

The process gas formed after the carrier gas passes through the evaporation source device 108 has a high-concentration MO source gas, while the process chamber 100 requires a low-concentration MO source gas. Therefore, in this embodiment, the gas delivery device further includes: a diluent carrier gas line 132, one end of the diluent carrier gas line 132 is in fluid communication with a dilution carrier gas source and the other end of the diluent carrier gas line 132 is in fluid communication with the process gas supply pipeline 107, and one end of a dilution process channel 131 is in fluid communication with the process gas supply pipeline 107 and the other end of the dilution process channel is in fluid communication with the shower head 101. The process gas in the process gas supply pipeline 107 is diluted by the carrier gas in the diluent carrier gas line 132, so that the process gas in the dilution process channel 131 has a low concentration to meet the requirement on the concentration of the process gas in the process chamber 100.

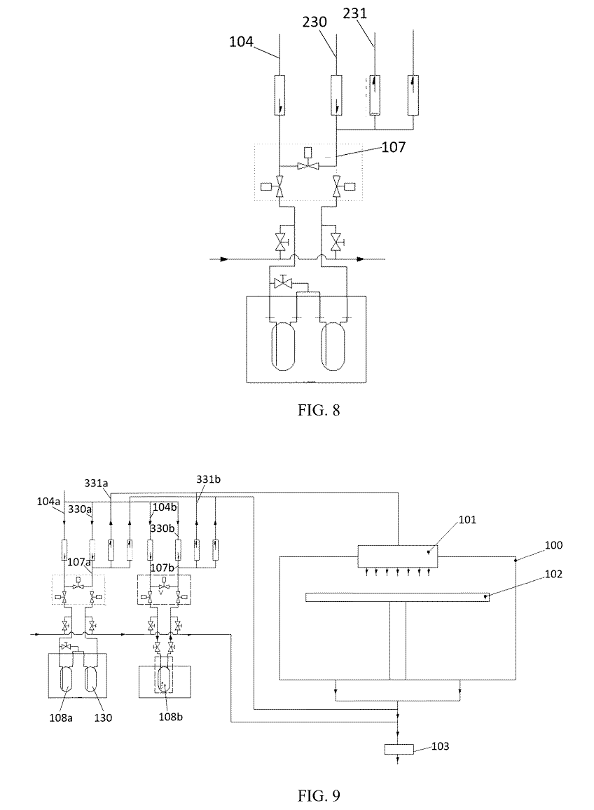

FIG. 8 is a schematic structural view of yet another semiconductor processing apparatus according to the present disclosure.

In FIG. 8, there are two evaporation source devices, and the purge gas pipeline, the first vent line, the second vent line, the carrier gas supply pipeline 104 and the process gas supply pipeline 107 are the same as those in FIG. 4, and will not be elaborated herein.

The MO source gas in the process gas supply pipeline 107 has a high concentration, while the process chamber requires a low-concentration MO source gas. Therefore, a diluent carrier gas line 230 is additionally provided, one end of the diluent carrier gas line 230 is in fluid communication with a dilution carrier gas source and the other end of the diluent carrier gas line 230 is in fluid communication with the process gas supply pipeline 107, and one end of a dilution process channel 231 is in fluid communication with the process gas supply pipeline 107 and the other end of the dilution process channel is in fluid communication with the shower head. The process gas in the process gas supply pipeline 107 is diluted by the carrier gas in the diluent carrier gas line 230, so that the process gas in the dilution process channel 231 has a low concentration to meet the requirement on the concentration of the process gas in the process chamber.

FIG. 9 is a schematic structural view of yet another semiconductor processing apparatus according to the present disclosure.

In FIG. 9, the first evaporation source device 108a and the second evaporation source device 130 are connected in series through the series channel, and the first evaporation source device 108a and the second evaporation source device 130 are connected in series and then connected to the third evaporation source device 108b in parallel.

In this embodiment, the carrier gas supply pipeline 104a and the carrier gas supply pipeline 104b share one carrier gas source, and the same as that in FIG. 6 further includes: the process gas supply pipeline 107a and the process gas supply pipeline 107b are merged and then input into the process chamber 100, and the purge gas pipeline, and the first vent line and the second vent line are the same as those in FIG. 6 and will not be elaborated herein.

The gas delivery device further includes: a first diluent carrier gas line 330a and a second diluent carrier gas line 330b, the first diluent carrier gas line 330a is configured to dilute the process gas in the process gas supply pipeline 107a, and the second diluent carrier gas line 330b is configured to dilute the process gas in the process gas supply pipeline 107b.

In this embodiment, the first diluent carrier gas line 330a, the second diluent carrier gas line 330b, the carrier gas supply pipeline 104a and the carrier gas supply pipeline 104b share one carrier gas source.

One end of the first diluent carrier gas line 330a is in fluid communication with the dilution carrier gas source, and the other end of the first diluent carrier gas line 330a is in fluid communication with the process gas supply pipeline 107a; one end of a first dilution process channel 331a is in fluid communication with the process gas supply pipeline 107a, and the process gas in the process gas supply pipeline 107a is diluted by the carrier gas in the first diluent carrier gas line 330a, so that the process gas in the first dilution process channel 331a has a low concentration; one end of the second diluent carrier gas line 330b is in fluid communication with the dilution carrier gas source, and the other end of the second diluent carrier gas line 330b is in fluid communication with the process gas supply pipeline 107b; one end of a second dilution process channel 331b is in fluid communication with the process gas supply pipeline 107b, and the process gas in the process gas supply pipeline 107b is diluted by the carrier gas in the second diluent carrier gas line 330b, so that the process gas in the second dilution process channel 331b has a low concentration; and the first dilution process channel 331a and the second dilution process channel 331b are merged and enter the process chamber 100 so as to meet the requirement on a low-concentration process gas in the process chamber 100.

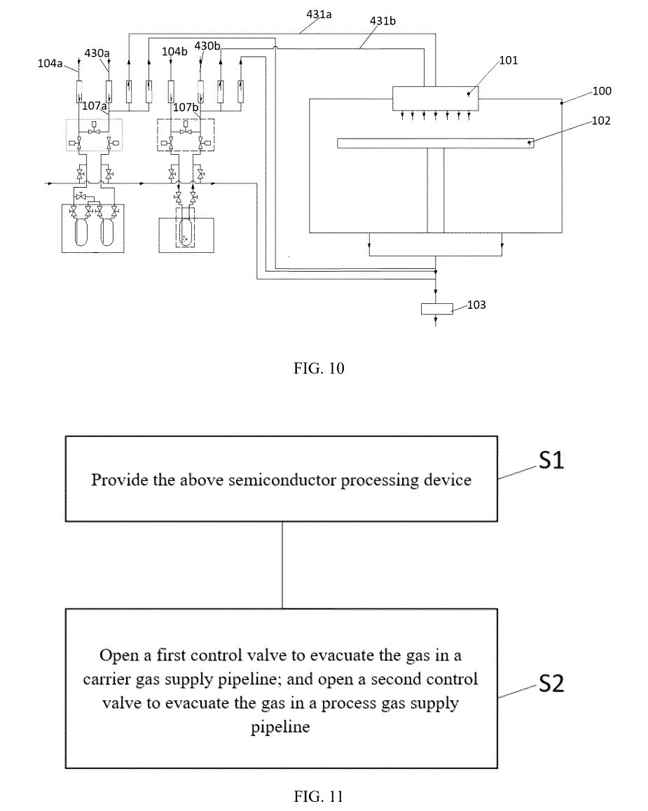

FIG. 10 is a schematic structural view of yet another semiconductor processing apparatus according to the present disclosure.

The embodiment shown in FIG. 10 is similar to the embodiment shown in FIG. 9, with the difference including: a first diluent carrier gas line 430a, a second diluent carrier gas line 430b, the carrier gas supply pipeline 104a and the carrier gas supply pipeline 104b respectively use different carrier gas sources.

The first diluent carrier gas line 430a is configured to dilute the process gas in the process gas supply pipeline 107a, the diluted process gas enters the process chamber 100 through a first dilution process channel 431a, the second diluent carrier gas line 430b is configured to dilute the process gas in the process gas supply pipeline 107b, the diluted process gas enters the process chamber 100 through a second dilution process channel 431b, and the first dilution process channel 431a and the second dilution process channel 431b respectively enter different inlets of the shower head 101. The diluted process gas is conveyed into the process chamber 100 to form a thin film on a surface of a wafer on the base 102.

Correspondingly, the present disclosure further provides an operating method of semiconductor processing apparatus, referring to FIG. 11, including: operation S1: the semiconductor processing apparatus is provided; and operation S2: the first control valve is opened to evacuate the gas in the carrier gas supply pipeline, and the second control valve is opened to evacuate the gas in the process gas supply pipeline.

The first vent line includes a first end and a second end; the first end is in fluid communication with the carrier gas supply pipeline, and the second end is in fluid communication with the purge inlet pipeline; a first pneumatic valve is disposed between the carrier gas source and the first end sequentially along a flow direction of the carrier gas; the second vent line includes a third end and a fourth end; the third end is in fluid communication with the process gas supply pipeline, and the fourth end is in fluid communication with the purge outlet pipeline; a second pneumatic valve is disposed between the third end and the process chamber along a flow direction of the process gas; and the operating method of the semiconductor processing apparatus further includes: when process treatment is performed in the process chamber, the first control valve and the second control valve are closed, and the first pneumatic valve and the second pneumatic valve are opened, so that the carrier gas enters the evaporation source device through the carrier gas supply pipeline to form saturated evaporation source vapor and carrier gas, that is, form a process gas, and the process gas is conveyed into the process chamber through the process gas supply pipeline to form a thin film on a surface of a wafer.

A first replacement valve is disposed between the first end and the inlet; a second replacement valve is disposed between the third end and the outlet; and when the evaporation source device is used or required to be replaced due to other reasons, the first control valve, the second control valve, the first pneumatic valve and the second pneumatic valve are closed, and the evaporation source device is disassembled through the first replacement valve and the second replacement valve. In the process of disassembling the evaporation source device, air tends to enter the carrier gas supply pipeline and the process gas pipeline. If cleaning is not performed before the next process, the air in the carrier gas supply pipeline will subsequently enter the evaporation source device along with the carrier gas to be in contact with the evaporation source gas, the contact between the air and the evaporation source gas is prone to cause explosion or reaction, and the air in the process gas supply pipeline will enter the process chamber along with the process gas to cause adverse influence on the process environment in the process chamber. To avoid these adverse influences, the first control valve on the first vent line can be opened to facilitate the discharge of the gas in the carrier gas supply pipeline, and the second control valve on the second vent line can be opened to facilitate the discharge of the gas in the process gas supply pipeline, so that it is beneficial to avoid the adverse influence on the subsequent process caused by undesirable gas remaining in the carrier gas supply pipeline and the process gas supply pipeline.

It should be noted that in this specification, relational terms such as the first and second are only used to distinguish one entity or operation from another entity or operation, and do not necessarily require or imply that there is any such actual relationship or order between these entities or operations. Furthermore, the term “comprises”, “includes” or any other variant thereof is intended to cover non-exclusive inclusion, so that a process, method, object or equipment including a series of elements not only includes those elements, but also includes other elements not explicitly listed, or also includes elements inherent to such process, method, object or equipment. Without further limitations, an element defined by the phrase “comprising a . . . ” does not exclude the presence of additional identical elements in the process, method, object or equipment including the element.

In the description of the present disclosure, it should be understood that the terms “center”, “height”, “thickness”, “upper”, “lower”, “vertical”, “horizontal”, “top”, “bottom”, “inside”, “outside”, “axial”, “radial”, “circumferential” and other directions or positional relationships indicated are those based on the directions or positional relationships shown in the drawings, only for the convenience of describing the present disclosure and simplifying the description, instead of indicating or implying that the device or element referred to must have a specific orientation, be constructed and operate in a specific orientation, it cannot be understood as a limitation of the present disclosure. In the description of the present disclosure, unless otherwise specified, “a plurality of” means two or more.

In the description of the present disclosure, unless otherwise specified and limited, the terms “mounting”, “connecting”, “connection” and “fixing” should be understood in a broad sense, for example, they may be a fixed connection, a detachable connection, or formed integrally; they may be a mechanical connection, or may be an electrical connection; may be a direct connection and may also be an indirect connection via an intermediate medium, or may be communication between the interiors of two elements or the interaction between two components. Those of ordinary skill in the art can understand the specific meanings of the above terms in the present disclosure in specific situations.

In the present disclosure, unless otherwise specified and defined, the first feature “above” or “below” the second feature may include direct contact between the first and second features, or contact between the first and second features through other features instead of direct contact. Moreover, the first feature “on”, “above” and “over” the second feature includes that the first feature is directly above and obliquely above the second feature, or only indicates that the horizontal height of the first feature is higher than the second feature. Moreover, the first feature “under”, “below” and “beneath” the second feature includes that the first feature is directly under and obliquely under the second feature, or only indicates that the horizontal height of the first feature is lower than that of the second feature.

Although the content of the present disclosure has been described in detail through the above preferred embodiments, it should be understood that the above description should not be considered as limiting the present disclosure. Various modifications and alternatives to the present disclosure will become apparent to those skilled in the art upon reading the foregoing disclosure. Accordingly, the protection scope of the present disclosure shall be limited by the appended claims.

What is claimed is:

1. A gas delivery device, comprising:
an evaporation source device, holding an evaporation source and comprising:
an inlet; and
an outlet;
a carrier gas supply pipeline, wherein a first end of the carrier gas supply pipeline is to be in fluid communication with a carrier gas source, a second end of the carrier gas supply pipeline is to be in fluid communication with the inlet, and carrier gas is to enter the evaporation source device and then to carry a saturated evaporation source gas to form a process gas;
a process gas supply pipeline, wherein a first end of the process gas supply pipeline is to be in fluid communication with the outlet, and a second end of the process gas supply pipeline is to be in fluid communication with a process chamber of a semiconductor processing apparatus; and
a purge gas pipeline, comprising:
a purge inlet pipeline to be in fluid communication with the carrier gas supply pipeline through a first vent line; and
a purge outlet pipeline to be in fluid communication with the process gas supply pipeline through a second vent line,
a first control valve disposed on the first vent line, and
a second control valve disposed on the second vent line, and
wherein the gas delivery device is configured to convey the process gas into the process chamber of the semiconductor processing apparatus.

2. The gas delivery device according to claim 1, wherein the first vent line comprises a first end and a second end, the first end is to be in fluid communication with the carrier gas supply pipeline, the second end is to be in fluid communication with the purge inlet pipeline, and a mass flow controller and a first pneumatic valve are disposed between the carrier gas source and the first end sequentially along a flow direction of the carrier gas.

3. The gas delivery device according to claim 2, wherein the second vent line comprises a third end and a fourth end, the third end is to be in fluid communication with the process gas supply pipeline, the fourth end is to be in fluid communication with the purge outlet pipeline, and a second pneumatic valve and a pressure controller are disposed between the third end and the process chamber along a flow direction of the process gas.

4. The gas delivery device according to claim 3, wherein a gas pipeline is disposed between an upstream of the first pneumatic valve and a downstream of the second pneumatic valve, and a third pneumatic valve is disposed on the gas pipeline.

5. The gas delivery device according to claim 3, wherein a first replacement valve is disposed between the first end and the inlet, and a second replacement valve is disposed between the third end and the outlet.

6. The gas delivery device according to claim 3, wherein the evaporation source device comprises a first evaporation source device and a second evaporation source device, the first evaporation source device comprises a first inlet and a first outlet, the second evaporation source device comprises a second inlet and a second outlet, the carrier gas supply pipeline is to be in fluid communication with the first inlet, the first outlet is to be in fluid communication with the second inlet through a series channel, a first replacement valve is disposed between the first end and the first inlet, a second replacement valve and a third replacement valve are disposed on the series channel, a fourth replacement valve is disposed between the third end and the second outlet, the first replacement valve and the second replacement valve are configured to replace the first evaporation source device, and the third replacement valve and the fourth replacement valve are configured to replace the second evaporation source device.

7. The gas delivery device according to claim 6, further comprising a switching channel comprising two opposite ends, a first end of the switching channel is to be in fluid communication with the carrier gas supply pipeline between the first end and a first replacement valve, a second end of the switching channel is to be in fluid communication with the series channel between a second replacement valve and a third replacement valve, and a switching valve is disposed on the switching channel.

8. The gas delivery device according to claim 7, further comprising a third evaporation source device, wherein the first evaporation source device is connected to the second evaporation source device in series and then connected to the third evaporation source device in parallel.

9. The gas delivery device according to claim 8, wherein the purge gas pipeline comprises a first purge gas pipeline and a second purge gas pipeline, the first purge gas pipeline comprises a first purge inlet pipeline and a first purge outlet pipeline, the first purge inlet pipeline is to be in fluid communication with the first vent line, the first purge outlet pipeline is to be in fluid communication with the second vent line, the first purge gas pipeline, the first vent line and the second vent line are configured to discharge air in pipelines of the first evaporation source device and the second evaporation source device, the second purge gas pipeline comprises a second purge inlet pipeline and a second purge outlet pipeline, the second purge inlet pipeline is to be in fluid communication with the carrier gas supply pipeline through a third vent line, and the second purge outlet pipeline is to be in fluid communication with the process gas supply pipeline through a fourth vent line.

10. The gas delivery device according to claim 9, wherein the first purge outlet pipeline is to be in fluid communication with the second purge inlet pipeline, the semiconductor processing apparatus further comprises a vacuum pump, and the second purge outlet pipeline is to be in fluid communication with the vacuum pump.

11. The gas delivery device according to claim 10, wherein the carrier gas source of the first evaporation source device and the second evaporation source device is independent of the carrier gas source of the third evaporation source device, and the process gas supply pipeline of the first evaporation source device and the second evaporation source device and the process gas supply pipeline of the third evaporation source device are respectively connected to different inlets of the process chamber.

12. The gas delivery device according to claim 10, wherein the first evaporation source device, the second evaporation source device and the third evaporation source device share a same carrier gas source, and the process gas supply pipeline of the first evaporation source device and the second evaporation source device and the process gas supply pipeline of the third evaporation source device are merged and then connected to a same inlet of the process chamber.

13. The gas delivery device according to claim 1, further comprising:
a diluent carrier gas line, wherein a first end of the diluent carrier gas line is to be in fluid communication with a dilution carrier gas source, and a second end of the diluent carrier gas line is to be in fluid communication with the process gas supply pipeline and is configured to dilute an output of the process gas from the evaporation source device to form a diluted process gas; and
a dilution process channel, wherein a first end of the dilution process channel is to be in fluid communication with the process gas supply pipeline, and a second end of the dilution process channel is to be in fluid communication with the process chamber.

14. The gas delivery device according to claim 10, the process gas supply pipeline of the first evaporation source device and the second evaporation source device being a first process gas supply pipeline, the process gas supply pipeline of the third evaporation source device being a second process gas supply pipeline, and the gas delivery device further comprising:
a first diluent carrier gas line and a second diluent carrier gas line, wherein a first end of the first diluent carrier gas line is to be in fluid communication with a first dilution carrier gas source, and a second end of the first diluent carrier gas line is to be in fluid communication with the first process gas supply pipeline and is configured to dilute an output of the process gas from the first evaporation source device and the second evaporation source device to form a first diluted process gas;
a first dilution process channel, wherein a first end of the first dilution process channel is to be in fluid communication with the first process gas supply pipeline, a second end of the first dilution process channel is to be in fluid communication with the process chamber, a first end of the second diluent carrier gas line is to be in fluid communication with a second dilution carrier gas source, and a second end of the second diluent carrier gas line is to be in fluid communication with the second process gas supply pipeline and is configured to dilute an output of the process gas from the third evaporation source device to form a second diluted process gas; and
a second dilution process channel, wherein a first end of the second dilution process channel is to be in fluid communication with the second process gas supply pipeline, and a second end of the second dilution process channel is to be in fluid communication with the process chamber.

15. The gas delivery device according to claim 14, wherein the carrier gas source of the first evaporation source device and the second evaporation source device, the carrier gas source of the third evaporation source device, the first dilution carrier gas source and the second dilution carrier gas source are independent of each other; and a first diluted process gas supply pipeline and a second diluted process gas supply pipeline are respectively connected to different inlets of the process chamber.

16. The gas delivery device according to claim 14, wherein the carrier gas source of the first evaporation source device and the second evaporation source device, the carrier gas source of the third evaporation source device, the first dilution carrier gas source and the second dilution carrier gas source share a same carrier gas source; and a first diluted process gas supply pipeline and a second diluted process gas supply pipeline are merged and then connected to a same inlet of the process chamber.

17. A semiconductor processing apparatus, comprising:
a process chamber;
a base, located at a bottom of the process chamber and configured to carry a wafer;
a shower head, disposed opposite to the base; and
a gas delivery device connected to the shower head and configured to convey a process gas into the process chamber, comprising:
an evaporation source device, holding an evaporation source and comprising:
an inlet; and
an outlet;
a carrier gas supply pipeline, wherein a first end of the carrier gas supply pipeline is to be in fluid communication with a carrier gas source, a second end of the carrier gas supply pipeline is to be in fluid communication with the inlet, and carrier gas is to enter the evaporation source device and then to carry a saturated evaporation source gas to form a process gas;
a process gas supply pipeline, wherein a first end of the process gas supply pipeline is to be in fluid communication with the outlet, and a second end of the process gas supply pipeline is to be in fluid communication with a process chamber of a semiconductor processing apparatus; and
a purge gas pipeline, comprising:
a purge inlet pipeline to be in fluid communication with the carrier gas supply pipeline through a first vent line; and
a purge outlet pipeline to be in fluid communication with the process gas supply pipeline through a second vent line,
a first control valve disposed on the first vent line, and
a second control valve disposed on the second vent line.

18. A method of operating a semiconductor processing apparatus, comprising:
providing the semiconductor processing apparatus, wherein the semiconductor processing apparatus comprises:
a process chamber;
a base, located at a bottom of the process chamber and configured to carry a wafer;
a shower head, disposed opposite to the base; and
a gas delivery device connected to the shower head and configured to convey a process gas into the process chamber, comprising:
an evaporation source device, holding an evaporation source and comprising:
an inlet; and
an outlet;
a carrier gas supply pipeline, wherein a first end of the carrier gas supply pipeline is to be in fluid communication with a carrier gas source, a second end of the carrier gas supply pipeline is to be in fluid communication with the inlet, and carrier gas is to enter the evaporation source device and then to carry a saturated evaporation source gas to form a process gas;
a process gas supply pipeline, wherein a first end of the process gas supply pipeline is to be in fluid communication with the outlet, and a second end of the process gas supply pipeline is to be in fluid communication with a process chamber of a semiconductor processing apparatus; and
a purge gas pipeline, comprising:
a purge inlet pipeline to be in fluid communication with the carrier gas supply pipeline through a first vent line; and
a purge outlet pipeline to be in fluid communication with the process gas supply pipeline through a second vent line,
a first control valve disposed on the first vent line, and
a second control valve disposed on the second vent line;
opening the first control valve to evacuate gas in the carrier gas supply pipeline; and
opening the second control valve to evacuate the gas in the process gas supply pipeline.

19. The method according to claim 18, wherein the first vent line comprises a first end and a second end; the first end is to be in fluid communication with the carrier gas supply pipeline, and the second end is to be in fluid communication with the purge inlet pipeline; a first pneumatic valve is disposed between the carrier gas source and the first end sequentially along a flow direction of the carrier gas; the second vent line comprises a third end and a fourth end; the third end is to be in fluid communication with the process gas supply pipeline, and the fourth end is to be in fluid communication with the purge outlet pipeline; a second pneumatic valve is disposed between the third end and the process chamber along a flow direction of the process gas; and the method further comprising:
in response to performing a process treatment in the process chamber, closing the first control valve and the second control valve; and
opening the first pneumatic valve and the second pneumatic valve.

20. The method according to claim 19, wherein a first replacement valve is disposed between the first end and the inlet; a second replacement valve is disposed between the third end and the outlet; and before the opening the first control valve and the opening the second control valve, the method further comprising:
closing the first control valve, the second control valve, the first pneumatic valve and the second pneumatic valve; and
disassembling the evaporation source device through the first replacement valve and the second replacement valve.
